(19) United States
(12) Patent Application Publication
(10) Pub. No.: US 2024/0204345 A1
(43) Pub. Date: Jun. 20, 2024

(54) BATTERY SYSTEM, AND ESS AND VEHICLE INCLUDING THE SAME

(71) Applicant: LG ENERGY SOLUTION, LTD., Seoul (KR)

(72) Inventors: Young-Hoo OH, Daejeon (KR); Seung-Hyun KIM, Daejeon (KR); Seung-Min OK, Daejeon (KR); Sang-Hyun JO, Daejeon (KR); Young-Bum CHO, Daejeon (KR); Sung-Goen HONG, Daejeon (KR)

(73) Assignee: LG ENERGY SOLUTION, LTD., Seoul (KR)

(21) Appl. No.: 18/287,124

(22) PCT Filed: Dec. 19, 2022
(86) PCT No.: PCT/KR2022/020756

§ 371 Date: Oct. 16, 2023

(30) Foreign Application Priority Data
Dec. 21, 2021 (KR) 10-2021-0184404
Dec. 24, 2021 (KR) 10-2021-0187683

(51) Int. Cl. H01M 50/383; B60L 3/00; B60L 50/64; H01M 10/48; H01M 10/613; H01M 10/625; H01M 10/6563; H01M 50/204; H05K 7/20

(52) U.S. Cl. CPC H01M 50/383; B60L 3/0046; H01M 10/486; H01M 10/613; H01M 10/625; H01M 10/6563; H01M 50/204; B60L 50/64; H01M 2220/20; H05K 7/20863

(57) ABSTRACT

A battery system includes a plurality of battery packs; a duct configured to communicate with the inside of each of the plurality of battery packs; and a cooling fan connected to the duct and configured to perform both the forward rotation and reverse rotation.

### TECHNICAL FIELD

The present disclosure relates to a battery system, and an energy storage system (ESS) and a vehicle including the same.

The present application claims priority to Korean Patent Application No. 10-2021-0184404 filed on Dec. 21, 2021 and Korean Patent Application No. 10-2021-0187683 filed on Dec. 24, 2021, the disclosures of which are incorporated herein by reference.

### BACKGROUND ART

A battery pack applied to a vehicle or an ESS may be manufactured in a form including a plurality of battery modules to which a secondary battery (e.g., lithium secondary battery) capable of realizing high output and high capacity is applied. In order to satisfy the output characteristics of the battery pack required by the device to which the battery pack is applied and to realize high capacity, the number of secondary batteries included in one battery module may be increased, and the number of battery modules included in one battery pack may be increased.

However, in the case of a battery pack including such a large number of secondary batteries, when a fire or explosion occurs, the damage is inevitably increased.

A fire occurring in a battery pack starts from an abnormal increase in temperature of a secondary battery disposed inside the battery module and generation of internal gas. When the temperature of the secondary battery rises abnormally and the internal pressure of the secondary battery rises above a certain level due to the generation of internal gas, venting occurs in the lithium secondary battery, whereby high-temperature gas may be emitted to the outside of the lithium secondary battery and high-temperature spark including an electrode active material, metal particles, and the like may be emitted.

In order to ensure safety in the use of the battery pack, the venting gas should be rapidly discharged to the outside of the battery pack so that the internal pressure of the battery pack no longer increases in the case of occurrence of an event. However, when the high-temperature spark together with the venting gas is discharged to the outside of the battery pack, the venting gas, the high-temperature spark, and oxygen may meet and cause a fire. In addition, when the venting gas and high-temperature spark discharged to the outside of the battery pack flow into an adjacent battery pack, a thermal event may spread and cause greater damage.

Therefore, when a thermal event occurs in some battery packs, it is required to develop a battery pack having a structure that may prevent fire-causing substances from spreading to adjacent battery packs and also suppress oxygen from flowing into the battery pack in which fire-causing substances exist.

### DISCLOSURE

### Technical Problem

The present disclosure is designed to solve the problems of the related art, and therefore the present disclosure is directed to preventing a thermal event from spreading to adjacent battery packs by controlling a discharge direction of a venting gas when a thermal event occurs in some battery packs in a battery system.

In another aspect, the present disclosure is directed to preventing oxygen from flowing into a battery pack having a problem when a thermal event occurs in some battery packs in a battery system.

In still another aspect, the present disclosure is directed to effectively blocking emission of a spark material to the outside of a battery pack when a thermal event occurs in some battery packs in a battery system.

However, technical problems to be solved by the present disclosure are not limited to the above-described problems, and other problems not mentioned herein may be clearly understood by those skilled in the art from the following description of the present disclosure.

### Technical Solution

A battery system according to an embodiment of the present disclosure for solving the above-described problems includes a plurality of battery packs; a duct configured to communicate with the inside of each of the plurality of battery packs; and a cooling fan connected to the duct and configured to perform both the forward rotation and reverse rotation.

The forward rotation may be a rotation in a direction in which cooling air is introduced into the plurality of battery packs through the duct, and the reverse rotation may be a rotation in a direction in which air inside the plurality of battery packs is discharged through the duct.

The cooling fan may be configured to perform the reverse rotation when a thermal event is detected in at least one of the plurality of battery packs.

The battery system may include a sensor configured to detect a thermal event when it occurs in at least one of the plurality of battery packs.

The sensor may be provided in each of the plurality of battery packs.

Each of the plurality of battery packs may include a first opening connected to the duct; and a second opening formed at a different location from the first opening.

The second opening may be configured to be opened when the cooling fan performs the forward rotation and closed when the cooling fan performs the reverse rotation.

The second openings provided in each of the plurality of battery packs may be configured to be opened and closed independently of each other.

The battery system may be configured such that when a thermal event occurs in at least one of the plurality of battery packs, the second opening provided in the battery pack where the thermal event occurs is closed, and the second opening provided in the other battery packs remains open.

The battery system may include a plurality of filters provided at each of the connection portions between the plurality of battery packs and the duct.

Each of the plurality of filters may be configured to be opened and closed.

Each of the plurality of filters may be configured to operate independently of each other.

The battery system may be configured such that when a thermal event occurs in at least one of the plurality of battery packs, a filter provided at a connection portion between the battery pack where the thermal event occurs and the duct among the plurality of filters performs a closing operation, and the other filters perform an opening operation.

Meanwhile, an ESS according to an embodiment of the present disclosure includes a battery system according to an embodiment of the present disclosure as described above.

A vehicle according to an embodiment of the present disclosure includes a battery system according to an embodiment of the present disclosure as described above.

### Advantageous Effects

According to one aspect of the present disclosure, it is possible to effectively prevent a thermal event from spreading to adjacent battery packs by controlling a discharge direction of a venting gas when a thermal event occurs in some battery packs in a battery system.

According to another aspect of the present disclosure, it is possible to effectively prevent oxygen from flowing into a battery pack having a problem when a thermal event occurs in some battery packs in a battery system.

According to still another aspect of the present disclosure, it is possible to effectively block emission of a spark material to the outside of a battery pack when a thermal event occurs in some battery packs in a battery system.

However, advantageous effects to be obtained by the present disclosure are not limited to the above-described effects, and other effects not mentioned herein may be clearly understood by those skilled in the art from the following description of the present disclosure.

### DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a conceptual diagram illustrating a battery system according to an embodiment of the present disclosure.

FIGS. 2 and 3 are views illustrating air flow when a cooling fan rotates in a forward direction in the battery system shown in FIG. 1.

FIGS. 4 and 5 are views illustrating air flow when a cooling fan rotates in a reverse direction in the battery system shown in FIG. 1.

FIGS. 6 and 7 are views illustrating an embodiment in which a sensor for detecting a thermal event is provided in the battery system shown in FIG. 1.

FIG. 8 is a view illustrating an embodiment in which a first opening and a second opening are provided in the battery pack of the present disclosure.

FIGS. 9 and 10 are views for describing the opening and closing of the second opening according to the forward and reverse rotation of a cooling fan.

FIG. 11 is a view illustrating an embodiment configured to independently perform an open/close operation of the second opening provided in each of a plurality of battery packs.

FIG. 12 is a view illustrating an embodiment in which a filter is provided at a connection portion between a battery pack and a duct in the battery system of the present disclosure.

FIGS. 13 and 14 are views illustrating installation positions of the filters shown in FIG. 12.

FIGS. 15 and 16 are views illustrating an embodiment configured to perform an open/close operation of the filter shown in FIG. 12.

FIGS. 17 and 18 are views for describing the opening and closing of the filter and the second opening in a normal state and a thermal event state.

FIG. 19 is a view illustrating an energy storage system (ESS) according to an embodiment of the present disclosure.

FIG. 20 is a view illustrating a vehicle according to an embodiment of the present disclosure.

### BEST MODE

Hereinafter, preferred embodiments of the present disclosure will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation. Therefore, the description proposed herein is just a preferable example for the purpose of illustrations only, not intended to limit the scope of the disclosure, so it should be understood that other equivalents and modifications could be made thereto without departing from the scope of the disclosure.

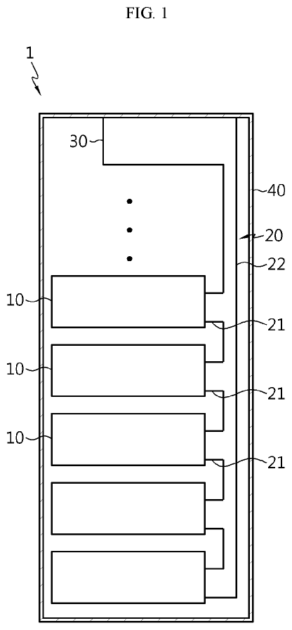

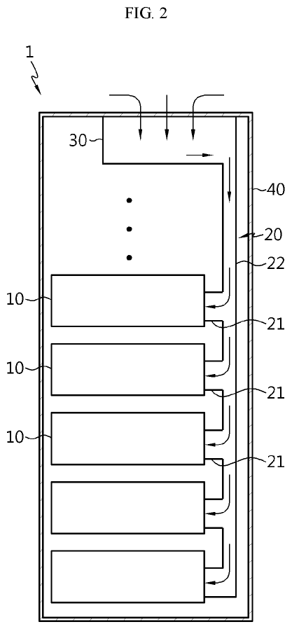

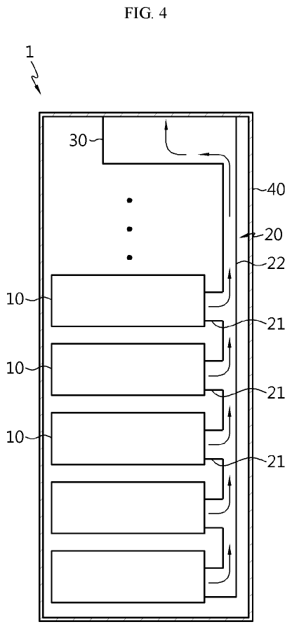

Referring to FIGS. 1 to 5, a battery system 1 according to an embodiment of the present disclosure may include a battery pack 10, a duct 20, and a cooling fan 30. The battery pack 10 may be provided in plurality. The duct 20 may be configured to communicate with the inside of each of the plurality of battery packs 10. The cooling fan 30 is connected to the duct 20 and may be configured to perform both the forward and reverse rotation.

In the battery system 1 having the above-described configuration, the circulation direction of air may be adjusted by controlling the rotation direction of the cooling fan 30. According to the configuration of the battery system 1, air may be smoothly supplied to the plurality of battery packs 10 when the battery system 1 is in a normal state. Meanwhile, according to the configuration of the battery system 1, when a thermal event occurs in the battery system 1, a fluid is induced to flow from the plurality of battery packs 10 toward the outside of the battery system 1, and thus it is possible to prevent a thermal event generated in some battery packs 10 from spreading to the other battery packs 10.

Meanwhile, the battery system 1 may include a battery housing 40 configured to accommodate the battery pack 10. The battery housing 40 may be configured to accommodate a duct 20 and/or a cooling fan 30 in addition to the battery pack 10. However, the present disclosure is not limited thereto, and a portion or all of the duct 20 and/or the cooling fan 30 may be exposed to the outside of the battery housing 40. The battery housing 40 may be, for example, a battery rack configured to load a plurality of battery packs 10 layer by layer. However, the present disclosure is not limited thereto, and the battery housing 40 may have different shapes depending on the use of the battery system 1 of the present disclosure, required capacity, output, and the like.

The forward rotation of the cooling fan 30 may refer to a rotation in a direction in which cooling air is introduced into each of the plurality of battery packs 10 through the duct 20. On the other hand, the reverse rotation of the cooling fan 30 may refer to a rotation in a direction in which air inside the plurality of battery packs 10 is discharged through the duct 20. Accordingly, the cooling fan 30 may be configured to perform the forward rotation when the battery system 1 is in a normal state. The cooling fan 30 may be configured to perform the reverse rotation when a thermal event is detected in at least one of the plurality of battery packs 10.

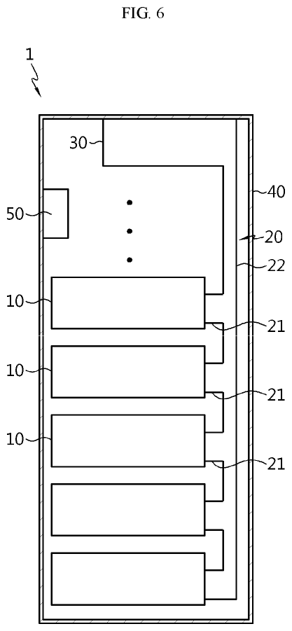

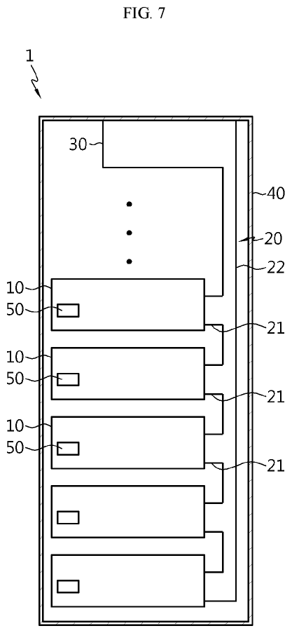

Meanwhile, the cooling fan 30 may be driven manually or automatically. For example, an operator or user may manually manipulate the rotation direction of the cooling fan 30 when a thermal event is detected. On the other hand, when a thermal event is detected through a sensor 50 (see FIGS. 6 and 7) to be described later, the rotation of the cooling fan 30 may be controlled according to a detection signal. For example, the battery system 1 may include a control unit (not shown), and the control unit outputs a driving control signal of the cooling fan 30 according to a signal detected by the sensor 50, whereby the cooling fan 30 may be driven.

The battery system 1 may be configured such that a fluid circulates between the cooling fan 30 and the battery pack 10 only through the duct 20. For example, as shown in FIG. 1, the duct 20 may include a plurality of branch portions 21 configured to communicate with the inside of each battery pack 10 and a main stream portion 22 configured to connect the plurality of branch portions 21 and the cooling fan 30.

According to the battery system 1 of the present disclosure configured as described above, the cooling air supplied into the battery system 1 through the cooling fan 30 may be supplied to the plurality of battery packs 10, and thus efficient cooling may be achieved without installing cooling fans individually for each battery pack 10. According to another aspect of the battery system 1 of the present disclosure configured as described above, discharge pressure of a fluid may be formed in a direction from the plurality of battery packs 10 toward the cooling fan 30. Accordingly, it is possible to prevent a phenomenon in which the high-temperature venting gas and/or high-temperature spark materials generated by the thermal event of some battery packs 10 are introduced into the inside of the other battery packs 10 while moving within the duct 20. According to still another aspect of the battery system 1 of the present disclosure configured as described above, when a thermal event occurs in at least one of the plurality of battery packs 10, a fluid flow may be made to the outside of the battery system 1 so that oxygen is not introduced into the battery system 1 where the high-temperature venting gas and/or high-temperature spark material exist. Therefore, it is possible to prevent the high-temperature venting gas and/or high-temperature spark material from meeting with oxygen and satisfying the conditions for ignition. The spark material may include, for example, an electrode active material and/or metal fragments discharged by venting due to an increase in internal pressure of a battery cell.

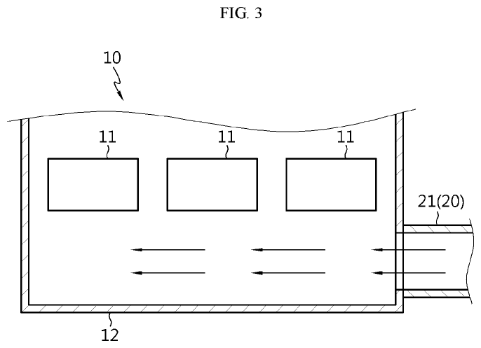

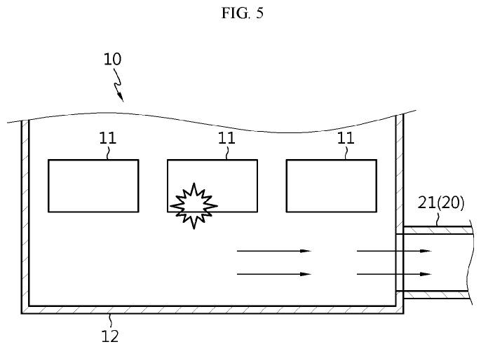

Meanwhile, referring to FIGS. 3 and 5, the battery pack 10 of the present disclosure may include a battery module 11 and a pack cover 12 configured to accommodate the battery module 11.

The battery module 11 may be provided in plurality. The battery module 11 may include a battery cell (not shown) and a module cover. The battery cell may be provided in plurality. However, the present disclosure is not limited thereto, and the module unit may be omitted and a plurality of battery cells may be directly accommodated in a pack cover. The pack cover 12 may have an opening. The duct 20 may communicate with the inner space of the pack cover 12 through the opening.

Next, referring to FIG. 6, the battery system 1 of the present disclosure may include a sensor 50. The sensor 50 may be configured to detect a thermal event when it occurs in at least one of the plurality of battery packs 10. The sensor 50 may be configured to detect, for example, temperature and/or gas and/or smoke caused by fire.

When the battery system 1 of the present disclosure includes the sensor 50 capable of detecting a thermal event, it is possible to rapidly detect the occurrence of a thermal event. Therefore, the rotation direction of the cooling fan 30 may be adjusted so that the cooling fan 30 performs the reverse rotation in response to the occurrence of a thermal event, thereby preventing the thermal event from spreading to the adjacent battery pack 10 and oxygen from flowing into the battery pack 10 where the thermal event has occurred.

Referring to FIG. 7, the sensor 50 may be provided in plurality. Each of the plurality of sensors 50 may be configured to independently detect a thermal event generated in each of the plurality of battery packs 10. For example, the number of sensors 50 may be at least equal to or greater than the number of battery packs 10. In this case, at least one sensor 50 may be provided for each battery pack 10.

As described above, when the battery system 1 of the present disclosure is configured to independently detect a thermal event generated in each of the plurality of battery packs 10, appropriate measures such as repair or replacement of the battery pack 10 where the thermal event occurs may be taken.

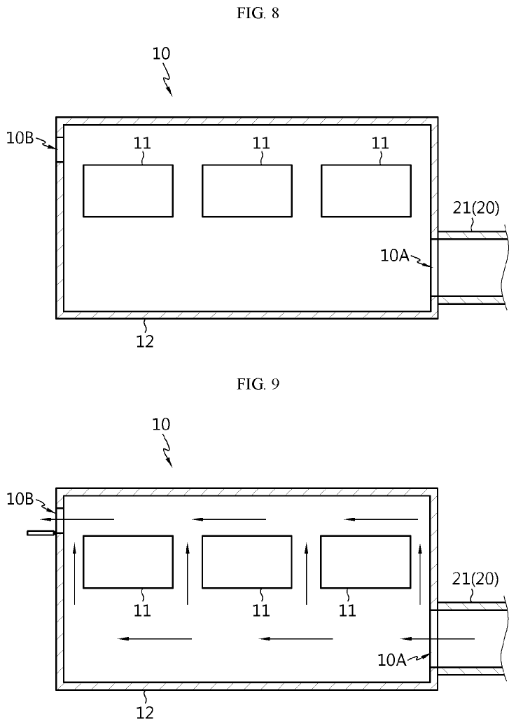

Next, referring to FIG. 8 together with FIG. 1, each of the plurality of battery packs 10 may include a first opening 10A and a second opening 10B. The first opening 10A may be connected to the duct 20. The second opening 10B may be formed at a different location from the first opening 10A.

When the battery pack 10 has the second opening 10B in addition to the first opening 10A connected to the duct 20 as described above, the flow of fluid passing through the inside of the battery pack 10 may be smooth.

The first opening 10A and the second opening 10B may be, for example, openings formed by partially penetrating the pack cover 12. The second opening 10B may be formed on the opposite side of the region where the first opening 10A is formed.

For example, the first opening 10A may be provided at one end of the flow path formed between the plurality of battery modules 11 disposed in the pack cover 12 and one side of the pack cover 12 in the extension direction. The second opening 10B may be provided at the other end of the flow path formed between the plurality of battery modules 11 disposed in the pack cover 12 and the other side of the pack cover 12 in the extension direction. In this case, cooling air introduced through the first opening 10A may pass between adjacent battery modules 11 and be discharged to the outside of the battery pack 10 through the second opening 10B.

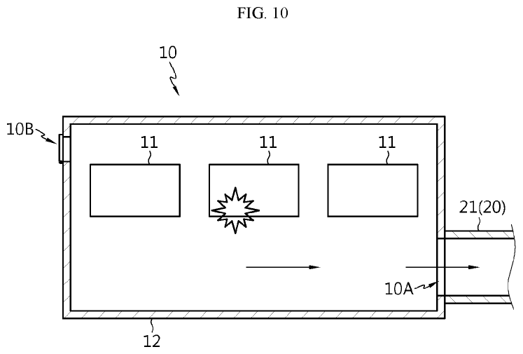

Next, referring to FIGS. 9 and 10 together with FIG. 1, the second opening 10B may be configured to be opened when the cooling fan 30 performs forward rotation and closed when the cooling fan 30 performs reverse rotation.

When the second opening 10B is operated in this way, it is possible not only to allow cooling air to be introduced more smoothly according to forward rotation of the cooling fan 30, but also to prevent oxygen from flowing into through the second opening 10B of the battery pack 10 where a thermal event occurs according to reverse rotation of the cooling fan 30.

Next, referring to FIG. 11, the second openings 10B provided in each of the plurality of battery packs 10 may be configured to be opened and closed independently of each other. According to this configuration, by controlling the second opening 10B to be opened or closed depending on whether the battery pack 10 has a thermal event, it is possible to effectively prevent oxygen from flowing into the battery pack 10 where the thermal event occurs while maintaining the overall flow of air discharged to the outside of the battery system 1 smoothly.

For example, the battery system 1 may be configured such that when a thermal event occurs in at least one of the plurality of battery packs 10, the second opening 10B provided in the battery pack 10 where the thermal event occurs is closed, and the second opening 10B provided in the other battery packs 10 remains open. In this case, the second opening 10B of the battery pack 10 (the battery pack located at the top in FIG. 11) where the thermal event occurs may be closed to prevent oxygen from flowing into through the second opening 10B of the battery pack 10. On the other hand, the second openings 10B of the remaining battery packs 10 where no thermal event occurs remain open, and thus the air introduced through the second openings 10B may smoothly flow through the first opening 10A, the duct 20, and the cooling fan 30 sequentially. When sufficient air discharge pressure is formed to smoothly flow air in one direction in this way, a risk that venting gas and/or spark material discharged from the battery pack 10 where the thermal event occurs flows backward to the other battery pack 10 may be minimized.

Meanwhile, opening and closing of the second opening 10B may be performed by, for example, an opening/closing member installed in the second opening 10B. The operation of the opening/closing member may be performed manually or automatically. For example, when a thermal event is detected, the operator or user may manually close the second opening 10B of all the battery packs 10 or only the second opening 10B of the battery packs 10 where the thermal event is detected. On the other hand, when a thermal event is detected through the sensor 50 (see FIGS. 6 and 7), it is possible to control the opening and closing of the second opening 10B according to the detection signal. For example, the battery system 1 may include a separate control unit (not shown), and the control unit may output a control signal for opening or closing of the second opening 10B according to a signal detected by the sensor 50, whereby the second opening 10B may be opened or closed.

Next, referring to FIG. 12, the battery system 1 of the present disclosure may include a plurality of filters 60 provided at each of the connection portions between the plurality of battery packs 10 and the duct 20. When the venting gas and spark material generated in the battery pack 10 where the thermal event has occurred move toward the outside of the battery pack 10 by reverse rotation of the cooling fan 30, the filter 60 may be configured to allow the venting gas to pass and the spark material to be filtered out. The filter 60 may be, for example, a mesh-type filter.

When the battery system 1 of the present disclosure includes the filter 60 as described above, it is possible to reduce both the internal pressure of the battery pack 10 due to the discharge of venting gas and the risk of fire due to the prevention of discharge of spark material. Moreover, when the spark material is filtered by the filter 60, the filter 60 becomes clogged over time, thereby reducing the possibility of oxygen inflow due to the decrease of the discharge pressure of the venting gas, resulting in greatly reducing the risk of fire and/or explosion inside the battery pack 10.

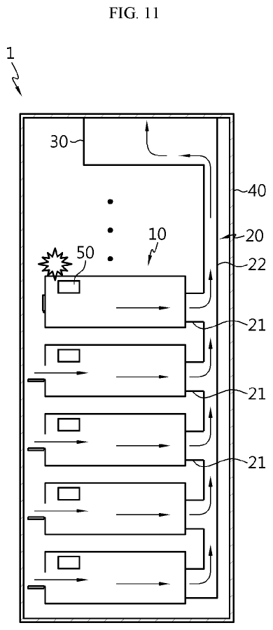

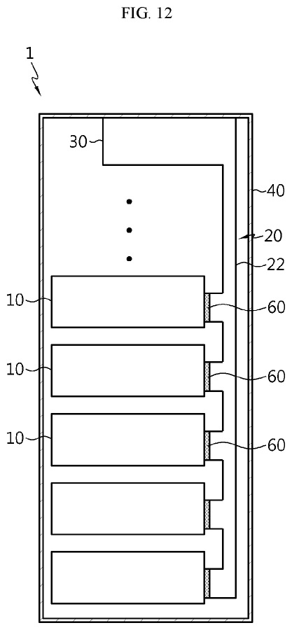

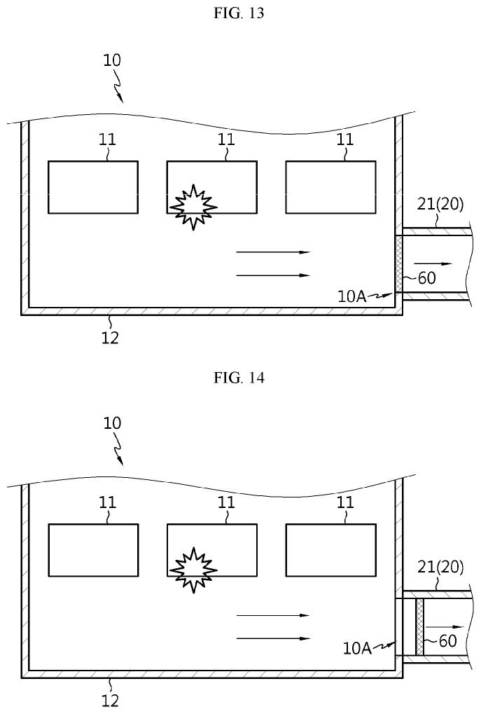

The filter 60 may be provided in the battery pack 10 as shown in FIG. 13. For example, the filter 60 may be configured to cover the first opening 10A formed in the pack cover 12 of the battery pack 10. Alternatively, the filter 60 may be provided in the duct 20 as shown in FIG. 14. The filter 60 may be provided, for example, in the branch portion 21 of the duct 20.

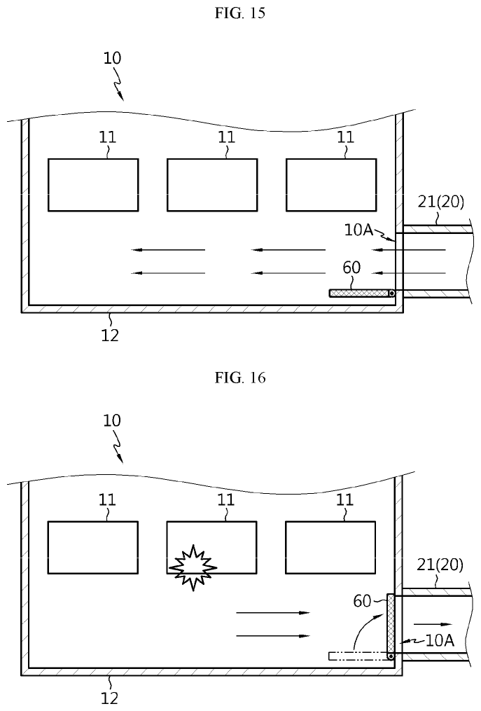

Next, referring to FIGS. 15 and 16, each of the plurality of filters 60 may be configured to be opened and closed. Each of the plurality of filters 60 may be configured to perform an opening operation during forward rotation of the cooling fan 30 (see FIG. 15) and a closing operation during reverse rotation of the cooling fan 30 (see FIG. 16). When the filter 60 performs an opening operation, the flow of cooling air into the battery pack 10 may be smoother. When the filter 60 performs a closing operation, the venting gas generated inside the battery pack 10 where the thermal event has occurred may be discharged to the outside through the duct 20, while the spark material may be filtered by the filter 60. Accordingly, it is possible to significantly reduce the risk of fire due to the blocking of discharge of the spark material while maintaining smooth reduction of internal pressure.

Meanwhile, each of the plurality of filters 60 provided at the connection portion between the plurality of battery packs 10 and the duct 20 may be configured to be independent of each other. For example, the battery system 1 may be configured such that when a thermal event occurs in at least one of the plurality of battery packs 10, the filter 60 provided at the connection portion between the battery pack 10 where the thermal event occurs and the duct 20 among the plurality of filters 60 performs a closing operation, and the other filters 60 perform an opening operation. When the battery system 1 is configured in this way, the spark material may be filtered only in the required region while maintaining a high discharge pressure of the fluid.

Meanwhile, the opening/closing operation of the filter 60 as described above may be controlled manually or automatically. For example, an operator or user may manually open the filter 60 when a thermal event is detected. On the other hand, when a thermal event is detected through the sensor 50 (see FIGS. 6 and 7), the closing operation of all filters 60 or the filter 60 installed at the connection portion between the battery pack 10 where the thermal event occurs and the duct 20 may be performed according to the detection signal. The battery system 1 may include a control unit (not shown), and the control unit may output an operation control signal of the filter 60 according to a signal detected by the sensor 50, thereby operating the filter 60.

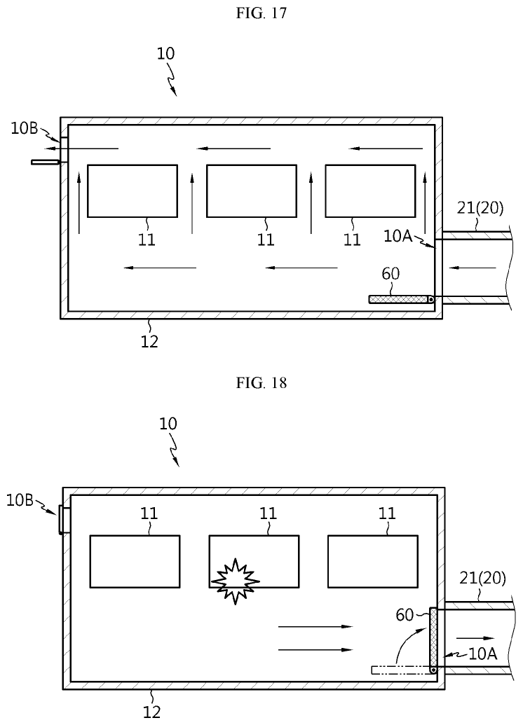

Next, referring to FIGS. 17 and 18, the filter 60 and the opening/closing member configured to open and close the second opening 10B may be configured to interlock with each other. For example, the opening/closing member and the filter 60 may perform the opening operation in the battery pack 10 where no thermal event is detected, and the opening/closing member and the filter 60 may perform the closing operation in the battery pack 10 where the thermal event is detected.

When both the filter 60 and the opening/closing member are in an open state during air inflow due to forward rotation of the cooling fan 30 (see FIG. 12), the flow of air passing through the battery pack 10 is smooth, and thus cooling efficiency may be improved. When both the filter 60 and the opening/closing member are in a closed state during air discharge due to reverse rotation of the cooling fan 30 (see FIG. 12), it is possible to prevent oxygen from flowing into the battery pack 10, to allow venting gas to be discharged to the outside smoothly, and to block the discharge of spark material.

Meanwhile, as described above, the operation of the cooling fan 30, the filter 60, and the opening/closing member configured to open and close the second opening 10B may be performed manually or automatically. When an automation system is applied, for example, the battery system 1 may include a control unit (not shown), and the control unit may output a control signal for controlling the operation of the cooling fan 30, the filter 60, and the opening/closing member of the second opening 10B according to a signal detected by the sensor 50, thereby interlocking the operation of each component.

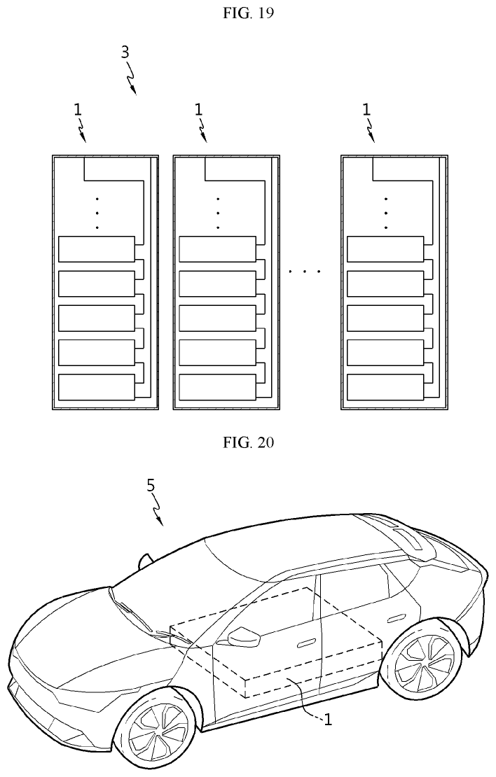

Referring to FIG. 19, an energy storage system (ESS) 3 according to an embodiment of the present disclosure may include a battery system 1 according to the present disclosure. The ESS 3 may include, for example, a plurality of battery systems 1.

Referring to FIG. 20, a vehicle 5 according to an embodiment of the present disclosure may include a battery system 1 according to the present disclosure. The vehicle 5 may include, for example, a plurality of battery systems 1. The vehicle 5 may be configured to operate by receiving power from the battery system 1. The vehicle 5 may be, for example, an electric vehicle (EV) or a hybrid electric vehicle (HEV).

While the present disclosure has been hereinabove described with regard to a limited number of embodiments and drawings, the present disclosure is not limited thereto and it is obvious to those skilled in the art that a variety of modifications and changes may be made thereto within the technical aspects of the present disclosure and the equivalent scope of the appended claims.

### REFERENCE SIGNS

1: battery system
3: energy storage system (ESS)
5: vehicle
10: battery pack
10A: first opening
10B: second opening
11: battery module
12: pack cover
20: duct
21: branch portion
22: main stream portion
30: cooling fan
40: battery housing
50: sensor
60: filter

1. A battery system comprising:
a plurality of battery packs;
a duct configured to communicate with the inside of each of the plurality of battery packs; and
a cooling fan connected to the duct and configured to perform both a forward rotation and a reverse rotation.

2. The battery system according to claim 1, wherein the forward rotation is a rotation in a direction in which cooling air is introduced into the plurality of battery packs through the duct, and the reverse rotation is a rotation in a direction in which air inside the plurality of battery packs is discharged through the duct.

3. The battery system according to claim 2, wherein the cooling fan is configured to perform the reverse rotation when a thermal event is detected in at least one of the plurality of battery packs.

4. The battery system according to claim 1, further comprising a sensor configured to detect a thermal event when it occurs in at least one of the plurality of battery packs.

5. The battery system according to claim 4, wherein the sensor is provided in each of the plurality of battery packs.

6. The battery system according to claim 1, wherein each of the plurality of battery packs comprises:
a first opening connected to the duct; and
a second opening formed at a different location from the first opening.

7. The battery system according to claim 6, wherein the second opening is configured to be opened when the cooling fan performs the forward rotation and closed when the cooling fan performs the reverse rotation.

8. The battery system according to claim 6, wherein the second openings provided in each of the plurality of battery packs are configured to be opened and closed independently of each other.

9. The battery system according to claim 8, wherein, when a thermal event occurs in at least one of the plurality of battery packs, the second opening provided in the at least one battery pack where the thermal event occurs is closed, and the second openings provided in remaining battery packs remain open.

10. The battery system according to claim 1, further comprising a plurality of connection portions between the plurality of battery packs and the duct, and a plurality of filters respectively provided at each of the plurality of connection portions.

11. The battery system according to claim 10, wherein each of the plurality of filters is configured to be opened and closed.

12. The battery system according to claim 11, wherein each of the plurality of filters is configured to operate independently of each other.

13. The battery system according to claim 12, wherein, when a thermal event occurs in at least one of the plurality of battery packs, a filter provided at the connection portion between the battery pack where the thermal event occurs and the duct among the plurality of filters performs a closing operation, and remaining filters are open.

14. An ESS comprising a battery system according to claim 1.

15. A vehicle comprising a battery system according to claim 1.
